(19) United States
(12) Patent Application Publication
(10) Pub. No.: US 2026/0353892 A1
(43) Pub. Date: Nov. 5, 2026

(54) INORGANIC THIN FILM ELECTROLUMINESCENT DISPLAY ELEMENT

(71) Applicant: LUMINEQ OY, Espoo (FI)

(72) Inventors: Jani HOLOPAINEN, Espoo (FI); Alexey GANZHINOV, Espoo (FI); Azad KARIS, Espoo (FI)

(21) Appl. No.: 19/109,139

(22) PCT Filed: Sep. 8, 2023
(86) PCT No.: PCT/FI2023/050515

§ 371 Date: Mar. 6, 2025

(30) Foreign Application Priority Data
Sep. 8, 2022 (FI) 20225783

(51) Int. Cl. H10H 29/80; H10H 29/01

(52) U.S. Cl. CPC H10H 29/842; H10H 29/034

(57) ABSTRACT

An inorganic thin film electroluminescent display element (100) has an operational layer structure (107) comprising a first and a second electrically conductive contact layer (101, 105), and a luminescent layer (103), comprising a luminescent material, positioned between the first and the second electrically conductive contact layer. The display element comprises a protective coating (108) on the second electrically conductive contact layer (105) on the side thereof opposite to the luminescent layer, the protective coating comprising a nanolaminate (109) with alternating sub-layers of aluminum oxide Al₂O₃ and a transition metal oxide TO₂ (111 , 110), wherein the nanolaminate comprises at least two sub-layers of each oxide type, and the transition metal T is hafnium Hf or zirconium Zr.

### BACKGROUND

Inorganic thin film electroluminescent (TFEL) displays are known as a feasible display technology especially in applications where rugged device configuration and reliable operation in harsh environments and extreme conditions is needed. There are however aspects where still improved solutions would be useful.

For example, leakage currents between parts such as conductor traces, segments, and/or filling areas of the transparent upper conductor layer should be prevented. One known solution is to have a protective coating of aluminum oxide on the upper transparent conductor layer typically formed of indium tin oxide ITO.

The upper conductor layer shall also be protected from the effects of moisture. For example, an EL display element may be encapsulated between a substrate glass and a cover glass mounted to the display element layer stack by an epoxy layer. However, the cover glass and epoxy are missing in the pad area for the electrical contacts, so additional moisture barrier is needed there. One known solution is to apply a silicone encapsulation on the pad area. However, any defect in the encapsulation may result in moisture penetrating through the aluminum oxide layer and damaging the ITO layer.

On the other hand, in the case of laminating an EL display element between two glass panels to form e.g. a windscreen of a vehicle, moisture present in the resin used in the lamination process may also cause problems if penetrating into the upper conductor layer. Also the optical properties of the protective coating need to be addressed to ensure proper transmission properties of the display element.

### SUMMARY

This summary is provided to introduce a selection of concepts in a simplified form that are further described below in the Detailed Description. This Summary is not intended to identify key features or essential features of the claimed subject matter, nor is it intended to be used to limit the scope of the claimed subject matter.

According to a device aspect, an inorganic thin film electroluminescent display element may be implemented, the display element having an operational layer structure comprising a first and a second electrically conductive contact layer, and a luminescent layer, comprising a luminescent material, positioned between the first and the second electrically conductive contact layers.

The display element comprises a protective coating on the second electrically conductive contact layer on the side thereof opposite to the luminescent layer, the protective coating comprising a nanolaminate with alternating Sub-layers of aluminum oxide Al₂O₃ and a transition metal oxide TO₂, wherein the nanolaminate comprises at least two sub-layers of each oxide type, and the transition metal T is hafnium Hf or zirconium Zr.

At least two, for example, five of the transition metal oxide TO₂ sub-layers may have a thickness of higher than or equal to 0.5 nm.

The nanolaminate may have a total thickness of higher than or equal to 25 nm, for example, higher than or equal to 100 nm, or higher than or equal to 200 nm.

The nanolaminate may have a total thickness of less than or equal to 700 nm, for example, less than or equal to 500 nm.

The nanolaminate may comprise more than 25 pairs of the aluminum oxide and transition metal oxide sub-layers.

The nanolaminate may have an overall atomic ratio of aluminum to transition metal in the range of 20/80 to 95/5, for example, 30/70 to 90/10.

The nanolaminate may have, in its thickness direction, zones with different aluminum to transition metal atomic ratios with the proportion of the transition metal increasing towards the second dielectric layer.

The protective coating may comprise, on the nanolaminate, on the side thereof opposite to the operational layer structure, an index matching layer of aluminum oxide Al₂O₃.

The protective coating may comprise, on the nanolaminate and possible index matching layer, on the side of the latter opposite to the operational layer structure, a capping layer of the transition metal oxide. The capping layer may have a thickness of 0.5 to 5 nm, for example, about 2 nm.

At least the second electrically conductive contact layer may comprise, or at least substantially consist of, indium tin oxide ITO.

There may be a contact opening formed in the protective coating for enabling electrical contact to be formed to the second contact layer. The contact opening may be formed by laser.

The nanolaminate may be formed by atomic layer deposition ALD.

In a second aspect, a method may be implemented for manufacturing an inorganic thin film electroluminescent display element in accordance with any of the embodiments of the device aspect above.

In the method, the nanolaminate may be formed by atomic layer deposition ALD.

For manufacturing a display element in accordance with the above device aspect embodiment comprising a contact opening formed in the protective coating, the contact opening may be formed by laser.

Many of the attendant features will be more readily appreciated as the same becomes better understood by reference to the following detailed description considered in connection with the accompanying drawings.

### BRIEF DESCRIPTION OF THE DRAWINGS

The present description will be better understood from the following detailed description read in view of the accompanying drawings, wherein:

FIG. 1 illustrates, as cross sectional view, a horizontally limited section of an inorganic thin film electroluminescent (EL) display element.

FIG. 2 illustrates, as P cross sectional view, a horizontally limited section of a protective coating of the display element of FIG. 1.

FIG. 3 illustrates a flow chart of method for manufacturing an inorganic thin film electroluminescent (EL) display element.

The drawings of the FIGS. are schematic illustrations drawn not to scale.

### DETAILED DESCRIPTION

The detailed description provided below in connection with the appended drawings is intended as a description of a number of embodiments and is not intended to represent the only forms in which the embodiments may be constructed, implemented, or utilized.

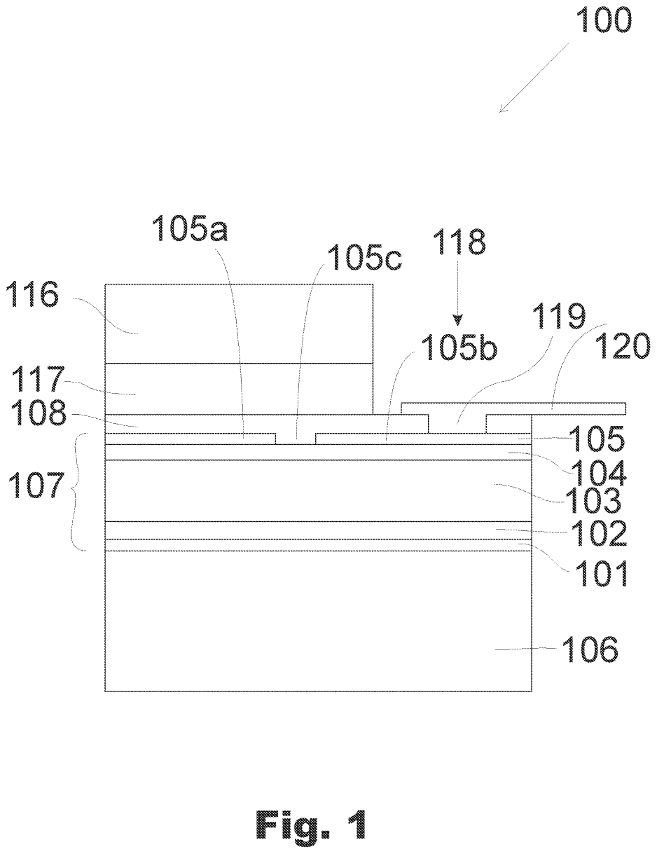

FIG. 1 shows, as a side sectional view, part of an inorganic electroluminescent (EL) display element 100.

A “display element” refers to an element which may form, as such, a complete, operable display. Alternatively, a display element may be used as one element of a complete display assembly comprising also other elements, units, and/or structures.

A “display” Is to Be Understood Broadly, Covering naturally “normal”, actual displays capable of displaying various patterns, images, or text, but also, for example, various control panels and user interface elements with at least one emissive area for emitting light therefrom.

The display element 100 is formed as a layered structure with a plurality of superposed layers.

A “layer” refers to a structural entity which may extend substantially along, or parallel to, a fictional base surface, and have a thickness in a direction perpendicular to said surface substantially smaller than the dimensions of the layer along or parallel to said surface. Such fictional base surface may be planar. Alternatively, it may be curved in one or more directions.

In the core of the EL display element 100 of FIG. 1, there is luminescent layer 103 superposed between a first electrically conductive contact layer 101 and a second electrically conductive contact layer 105. The luminescent layer is separated from the contact layers by a first dielectric layer 102 and a second dielectric layer 104. The luminescent layer thus lies on the first dielectric layer and the second dielectric layer lies on the luminescent layer. Thereby, the luminescent layer is adjacent to both the first and the second dielectric layers.

A layer lying “on” another layer or other structure refers in this specification to the layer lying “above” the other layer or structure with the upwards direction being defined in the thickness direction of the display element, from the first contact layer towards the second contact layer. Position “on” another layer r object does not exclude the possibility that there is a further intermediate layer or structure between the first mentioned layer and the other layer or structure on which it lies.

In other embodiments, EL display elements may be implemented with one dielectric layer only. Thus, an EL display element may comprise one or two dielectric layers. In the case of an EL display element comprising one single dielectric layer only, the dielectric layer may lie between the luminescent layer and the first contact layer or between the luminescent layer and the second contact layer.

The dielectric layers may be formed of any appropriate electrically insulating material(s) and have any appropriate thickness. They may further comprise sub-layers of different materials.

A dielectric layer may be substantially made of one single material. In other embodiments, it may comprise sub-layers of different material compositions.

In the example of FIG. 1, at least the second, i.e. the upper contact layer 105 in the drawing of FIG. 1 comprises, and may be substantially completely made of, indium tin oxide ITO. Being made of ITO, the upper contact layer may be transparent. In other embodiments, instead of ITO, any other transparent electrically conductive material such as aluminum doped zinc oxide AZO may be used. Also the lower contact layer may be formed of ITO, AZO, or any other appropriate transparent electrically conductive material, whereby the entire display element may be transparent. Alternatively, it may be formed of any appropriate opaque electrically conductive materials(s).

The display element 100 is formed on a glass substrate 106. In other embodiments, a plastic substrate may be used. The substrate may be transparent.

The display element 100 is designed to operate basically in accordance with the known operating principles of inorganic thin film EL displays. The contact layers 101, 105 serve for providing electrical connections of the display element. They may be patterned into any appropriate contact electrode configuration. For example, they may be patterned into segments of a segment type display element. In other embodiments, they may be patterned into crossing electrodes of a matrix type display element. In yet other embodiments, any other appropriate contact electrode configurations may be used. In FIG. 1, patterning is illustrated by two regions 105a, 105b of the second contact layer being separated from each other by a gap 105c.

In addition to electrodes, the contact layers may have any appropriate number and configuration(s) of conductor traces to form the electrical connections between the electrodes and the control electronics of the display. A contact layer may also comprise one or more filling areas, i.e. areas where the electrically conductive material is present but which are isolated from the other parts of the contact layer.

The luminescent layer may comprise any appropriate luminescent material(s), such as manganese doped zinc sulfide ZnS:Mn.

The luminescent layer may be substantially made of one single material. In other embodiments, it may comprise sub-layers of different material compositions.

A voltage difference between the first and second contact layers 101, 105 provides an electric field, by the effect of which the electrons move in the luminescent layer 103 and some of them excite so-called luminescent centers which are formed by the doping material(s) of the luminescent layer. Light is emitted as the excitation of the luminescent centers is relaxed. The luminescent layer may therefore be also called an emissive layer.

Thereby, the contact layers 101, 105 and the luminescent layer 103 as well as the dielectric layers 102, 104 therebetween form the actual operational layer structure 107 of the display element. “Operational” refers here to the layers and parts directly participating in the actual light generation by the electroluminescent process.

The basic technology of EL displays is known and has been described extensively e.g. in “Electroluminescent Displays” (Yoshimasa A. Ono, World Scientific Publishing Co., 1995 (ISBN 981-02-1920-0) in Chapters 3,5 and 8.

The display element 100 of FIG. 1 is implemented as a thin film (TF) EL display element.

The “thin film” nature of the display element refers to the total thickness of the layer structure of the operational layer structure, said total thickness being less than some tens of micrometers. The total thickness may be also substantially lower, for example, in the range of 1 to 10 μm, or less than 1 μm. Individual layers may basically have thicknesses, for example, in the range of a few nanometers to some tens or hundreds of nanometers or some micrometers.

In addition to the operational layer structure 107, the display element 100 of FIG. 1 comprises a protective coating 108 formed on the second contact layer 105. “On” refers here to the position of the protective coating on the side of the second contact layer which is opposite to the luminescent layer.

As illustrated in FIG. 1, in the protective coating 108 fills the gaps between different parts of the patterned second contact layer.

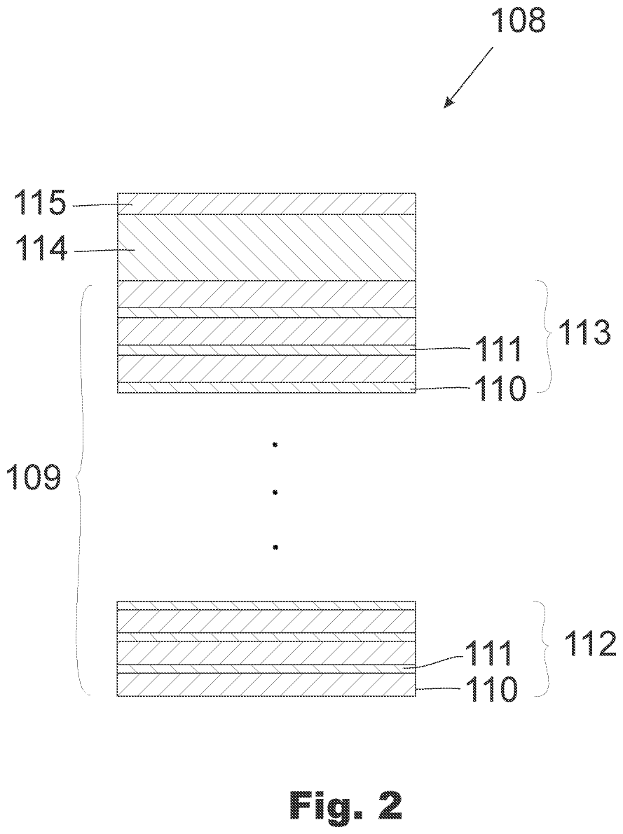

Advantageously, as illustrated in more detail in FIG. 2, the protective coating 108 of the display element 100 of FIG. 1 comprises a nanolaminate 109 with alternating layers of hafnium oxide HfO₂ and aluminum oxide Al₂O₃ 110, 111.

In other embodiments, instead of hafnium oxide, the other oxide may be zirconium oxide. Both hafnium and zirconium oxide are transition metals, so the other oxide may be called a transition metal oxide.

The prefix “nano” of the nanolaminate refers to the thickness of the alternating sub-layers lying in nanometer scale, i.e. having a thickness of less than or equal to a few to some dozens of nanometers.

Further, a nanolaminate with “alternating sub-layers” of two materials refers to the nanolaminate comprising at least two sub-layers of each of the two materials, thus at least four sub-layers altogether. Above this lower limit, the nanolaminate may comprise any appropriate number of pairs of two adjacent sub-layers of different materials. In some embodiments, it may be advantageous from the moisture resistance and leakage current prevention points of view that the nanolaminate comprises more than 25 pairs of the sub-layers of different oxides.

In the example of FIG. 2, the lowermost sub-layer, i.e. the sub-layer adjacent the second contact layer 105 is formed of hafnium oxide. In other embodiments, the lowermost sub-layer may be formed of aluminum oxide.

In the example of FIG. 2, the nanolaminate 109 comprises an even number of the sub-layers. In other embodiments, the nanolaminate may comprise an odd number of sub-layers, with the outermost sub-layers thereof being of the same oxide.

It may be advantageous that at least some of the hafnium oxide sub-layers 110, or zirconium oxide sub-layers in embodiments with zirconium as the transition metal, have a thickness of at least 0.5 nm. Such thickness may ensure that the sub-layer is sufficiently continuous to actually form a non-interrupted layer, thereby enabling formation of a true nanolaminate.

In various embodiments, the total thickness of the nanolaminate can vary depending on the number and thicknesses of the individual sub-layers. It has been found that electrically and optically useful properties may be achieved by having the total thickness of the nanolaminate at least 25 nm, for example, at least 100 nm, or at least 200 nm. The upper limit may vary, for example, between 500 and 700 nm. With too low total thickness, there may be undesirable leakage currents. On the other hand, increasing the thickness too much may deteriorate the optical transmission, and/or complicate the formation of contact opening(s) through the protective coating.

As illustrated in FIG. 2, the different types of sub-layers 110, 111 of the nanolaminate 109 may have different thicknesses. This may affect the proportions of aluminum and transition metal oxides ratio in the nanolaminate. It may be advantageous to have the overall aluminum to transition metal ratio in the nanolaminate in the range of 20/80 to 95/5 or, for example, in the range of 30/70 to 90/10.

It has been surprisingly found that a nanolaminate as described above may provide good electrical, moisture resistance, and optical properties. First, the protective coating comprising the nanolaminate may reduce the leakage currents between different regions of the upper, i.e. second, contact layer. The nanolaminate may also stop or restrain diffusion of water moisture, thereby protect the second contact layer and the layers underneath it from adverse effects of moisture. Further, the nanolaminate may serve as an optical intermediate layer improving the light transmission out of the display element.

In the example of FIGS. 1 and 2, the nanolaminate comprises, in its thickness direction, zones with different aluminum to transition metal atomic ratio. This is implemented by having the sub-layer thicknesses differing between the different zones. In the first or lowermost zone 112 adjacent to the second contact layer 105, the aluminum oxide sublayers are thinner relative to the transition metal sub-layers than in the last or uppermost zone 113 lying farthest from the second contact layer. This means that the aluminum to transition metal atomic ratio is higher in the last zone than in the first zone. The proportion of the transition metal in the nanolaminate thereby increases towards the second dielectric layer.

There may be any number of further zones between the first and the last zones such that the above principle of the proportion of the transition metal increasing towards the second dielectric layer is met. In such arrangement, the aluminum to transition metal atomic ratio and thus the proportions of aluminum and the transition layer change gradually in the nanolaminate thickness direction.

The change of the atomic ratio may also change the effective refractive index of the nanolaminate 109. “Effective” refractive index refers to that as the sub-layers have their thicknesses in the nanometer scale, well below the wavelengths of hundreds of nanometers, light waves experience the nanolaminate not as separate sub-layers having the bulk refractive indices of their materials, but as a single material with an effective refractive index between the refractive indices of the two materials.

As the proportional thicknesses of the different sub-layer types and thus the aluminum to transition metal atomic ratio changes between the different zones, so does the effective refractive index. Then, with suitable adjustment of the sub-layer thicknesses, the nanolaminate may have an effective refractive index gradually changing in the nanolaminate thickness direction. This may enable the nanolaminate to serve as an efficient anti-reflection coating minimizing the reflection losses between the operational layers of the display element and the cover glass or the upper glass sheet in embodiments where the display element is laminated between two glass sheets.

It is thereby possible to adjust in the first zone the thicknesses of the different type sub-layers to produce, at relevant wavelength(s), an effective refractive index close to the bulk refractive index of the second contact layer. “Relevant wavelengths” may, for example, refer to the wavelength(s) of the of the light emitted by the luminescent layer, or to the whole visible light wavelength range of about 400-700 nm. For example, for ZnS:Mn as the luminescent layer material, relevant wavelength may be the emission peak wavelength of, for example, 580 nm. For example, in the case of ITO as the second contact layer material, the effective refractive index of the first zone can be close to the bulk refractive index of ITO at 580 nm. That may be, for example, about 1,90.

As part of the optical optimization of the protective coating of FIGS. 1 and 2, there is an additional index matching layer 114 of aluminum oxide Al₂O₃ on the nanolaminate 109. This additional aluminum oxide layer may be thicker than the sub-layers of the nanolaminate. With sufficient thickness, such layer may operate optically as bulk aluminum oxide. The refractive index of aluminum oxide, for example, at 580 nm, may be about 1.6 which may be close to the refractive index, at said wavelength, of the epoxy or other adhesive used to mount the cover glass to the display element layer stack. Thereby, the index matching layer may serve for optically matching the outermost or upper part of the protective coating to the adhesive layer.

Correspondingly, in embodiments where the display element is laminated between two glass panels, the aluminum oxide index matching layer may serve for optically matching the protective coating to the lamination polymer such as polyvinyl butyral PVB or thermoplastic polyurethane TPU.

The protective coating 108 of FIGS. 1 and 2 further comprises a capping layer 115 of HfO₂ lying on the nanolaminate 109 and the additional index matching Al₂O₃ layer 114.

In other embodiments, especially those with zirconium oxide ZrO₂ as the transition metal oxide of the nanolaminate, the capping layer may be formed of zirconium oxide ZrO₂. It is also possible to have a capping layer of HfO₂ in an embodiment with zirconium oxide ZrO₂ as the transition metal oxide of the nanolaminate, and vice versa.

In other embodiments, protective coatings may be implemented without an Al₂O₃ index matching layer. Then, there may be however a HfO₂ or ZrO₂ capping layer on the nanolaminate.

Also embodiments without any capping layer are possible.

The HfO₂ capping layer 115 may advantageously improve the protective coating performance by forming an efficient barrier against moisture, preventing the moisture from penetrating into the nanolaminate and further to the operational layers of the display element.

The capping layer of the display element of FIG. 1 has a thickness of about 2 nm. In other embodiments, capping layer thicknesses in the range of, for example, 0.5 to 5 nm may be used.

As mentioned above, in the display element 100 of FIG. 1, there is a cover glass 116 mounted on the protective coating 108 by means of a layer of epoxy 117 or some other suitable adhesive with appropriate optical properties. Thereby, the display element 100 of FIG. 1 is encapsulated between the glass substrate 106 and the cover glass 116.

In the example of FIG. 1, there is a pad area 118 in the display element layout for forming an electrical connection between the upper or second contact layer 105 and control electronics (not illustrated) configured to drive the display element.

In the pad area 118, the cover glass 116 is missing. Further, a contact opening 119 is formed in the protective coating 108 to expose the second contact layer 105. The contact opening may be formed afterwards by removing the protective coating by means of a laser. By means of a laser, the protective coating materials may be removed by ablation. Using laser ablation, the contact opening formation may be accurately controlled both the in the horizontal and vertical directions, i.e. in the direction along the base surfaces of the layers and sub-layers and in the thickness direction thereof.

In addition to the pad area, further contact opening(s) formed by laser or by some other means may exist also at other location(s) where connection through the protective coating is desired.

A conductor trace 120 is formed on the protective layer 108 to extend to the pad area 118 and be in contact with the second contact layer 105 location exposed by the contact opening 119. The conductor trace may be formed e.g. of any appropriate metal such as copper, or any other appropriate material with suitable electrical conductivity.

It is to be noted that FIGS. 1 and 2 shows illustrations of horizontally, i.e. in the direction of the fictional base surfaces of the layers, limited sections of the display element (100) and the protective coating (108), respectively. Thus in the horizontal direction, the display element and the nanolaminate may extend further than illustrated in the drawings.

The nanolaminate of any of the embodiments above may be formed by atomic layer deposition ALD.

ALD refers to a thin film technology enabling accurate and well controlled production of thin film coatings with nanometer-scaled thicknesses. ALD may also be called Atomic Layer Epitaxy ALE. In an ALD process, the substrate is alternately exposed to at least two precursors, one precursor at a time, to form on the substrate a coating by alternately repeating essentially self-limiting surface reactions between the surface of the substrate (on the later stages, naturally, the surface of the already formed coating layer on the substrate) and the precursors. As a result, the deposited material is “grown” on the substrate molecule layer by molecule layer.

It may be preferable to utilize ALD not only in the formation of the nanolaminate but also the operational layers, possible Al₂O₃ index matching layer, and/or possible HfO₂ capping layer.

ALD provides a well-controlled process by which designed layer and sub-layer thicknesses may be produced with high accuracy and high material quality.

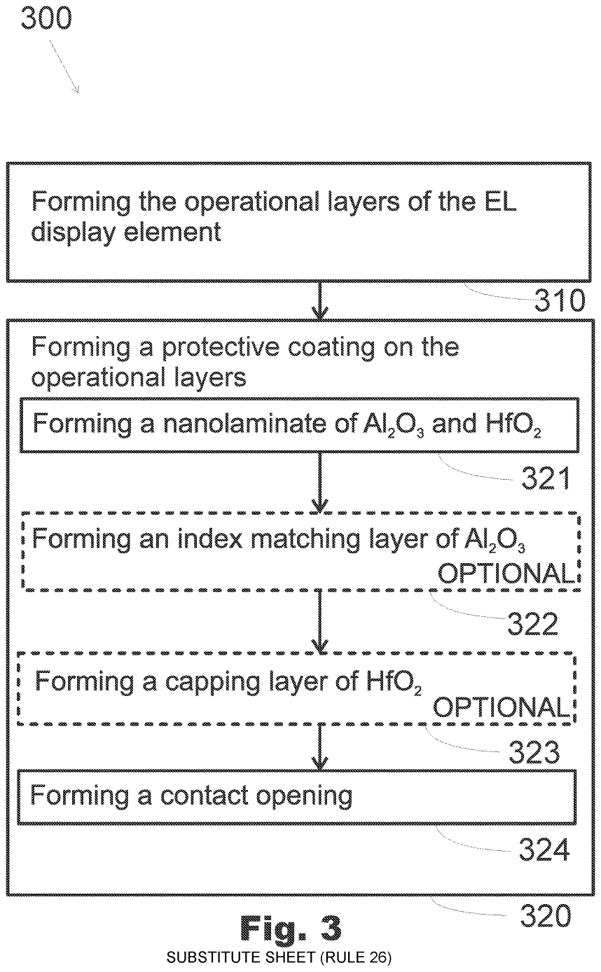

Any of the display elements discussed above with reference to FIG. 1 may be manufactured using the method discussed below with reference to FIG. 3. On the other hand, those display elements discussed above represent examples of display elements which can be manufactured by the methods discussed below. The details, definitions, and advantages of display elements discussed above apply also to the display elements discussed below in the context of the manufacturing method.

The method 300 of FIG. 1 starts, in phase 310, forming the operational layers of the EL display element on a glass or plastic substrate.

In phase 320, a protective coating is formed on the operational layers, actually on the second contact layer.

First, in sub-operation 321, the protective coating is formed so as to comprise a nanolaminate with alternating sub-layers of aluminum oxide Al₂O₃ and a transition metal oxide TO₂, wherein the nanolaminate comprises at least two sub-layers of each oxide type, and the transition metal T is hafnium Hf zirconium Zr.

As part of the formation of the protective coating, an aluminum oxide index matching layer and a hafnium oxide capping layer may be formed on the nanolaminate in optional sub-operations 322 and 323, respectively.

In the above operations, at least the nanolaminate, possibly all the layers, are formed using atomic layer deposition ALD. In the deposition, precursors and process parameters such as temperatures known in the art may be used.

To enable formation of electrical contacts to the second contact layer, in sub-operation 324, a contact opening is formed in the protective coating to expose the second contact layer. Preferably, opening is formed by laser ablation.

There may be any appropriate further sub-operations carried between any of the sub-operations discussed above. Thereby, it is not necessary that the above sub-operations follow immediately each other.

It is to be noted that the EL display element and the method for manufacturing the same are not limited to the embodiments and examples above. Instead, the embodiments may freely vary within the scope of the claims.

It will be understood that the benefits and advantages described above may relate to one embodiment or example or may relate to several embodiments or examples. The embodiments and examples are not limited to those that solve any or all of the stated problems or those that have any or all of the stated benefits and advantages. It will further be understood that reference to ‘an’ item refers to one or more of those items.

The term “comprising” is used in this specification to mean including the feature(s) followed thereafter, without excluding the presence of one or more additional features.

1. An inorganic thin film electroluminescent display element with an operational layer structure comprising
a first and a second electrically conductive contact layer, and
a luminescent layer, comprising a luminescent material, positioned between the first and the second electrically conductive contact layers, characterized in that the display element comprises a protective coating on the second electrically conductive contact layer on the side thereof opposite to the luminescent layer, the protective coating comprising a nanolaminate with alternating sub-layers of aluminum oxide Al₂O₃ and a transition metal oxide TO₂, wherein the nanolaminate comprises at least two sub-layers of each oxide type, and the transition metal T is hafnium Hf or zirconium Zr.

2. An inorganic thin film electroluminescent display element as defined in claim 1, wherein at least two, for example, five of the transition metal oxide TO₂ sub-layers have a thickness of higher than or equal to 0.5 nm.

3. An inorganic thin film electroluminescent display element as defined in claim 1, wherein the nanolaminate has a total thickness of higher than or equal to 25 nm, for example, higher than or equal to 100 nm, or higher than or equal to 200 nm.

4. An inorganic thin film electroluminescent display element as defined in claim 1, wherein the nanolaminate has a total thickness of less than or equal to 700 nm, for example, less than or equal to 500 nm.

5. An inorganic thin film electroluminescent display element as defined in claim 1, wherein the nanolaminate comprises more than 25 pairs of the aluminum oxide and transition metal oxide sub-layers.

6. An inorganic thin film electroluminescent display element as defined in claim 1, wherein the nanolaminate has an overall atomic ratio of aluminum to transition metal in the range of 20/80 to 95/5, for example, 30/70 to 90/10.

7. An inorganic thin film electroluminescent display element as defined in claim 1, wherein the nanolaminate has, in its thickness direction, zones with different aluminum to transition metal atomic ratios with the proportion of the transition metal increasing towards the second dielectric layer.

8. An inorganic thin film electroluminescent display element as defined in claim 1, wherein the protective coating comprises on the nanolaminate, on the side thereof opposite to the operational layer structure, an index matching layer of aluminum oxide Al₂O₃.

9. An inorganic thin film electroluminescent display element as defined in claim 1, wherein the protective coating comprises, on the nanolaminate, on the side thereof opposite to the operational layer structure, a capping layer of the transition metal oxide.

10. An inorganic thin film electroluminescent display element as defined in claim 8, wherein the capping layer has a thickness of 0.5 to 5 nm, for example, about 2 nm.

11. An inorganic thin film electroluminescent display element as defined in claim 1, wherein at least the second electrically conductive contact layer comprises indium tin oxide ITO.

12. An inorganic thin film electroluminescent display element as defined in claim 1, wherein there is a contact opening formed in the protective coating for enabling electrical contact to be formed to the second contact layer.

13. An inorganic thin film electroluminescent display element as defined in claim 12, wherein the contact opening is formed by laser.

14. An inorganic thin film electroluminescent display element as defined in claim 1, wherein the nanolaminate is formed by atomic layer deposition ALD.

15. A method for manufacturing an inorganic thin film electroluminescent display element as defined in claim 1.

16. A method as defined in claim 15, wherein the nanolaminate is formed by atomic layer deposition ALD.

17. A method as defined in claim 15, wherein the contact opening is formed by laser.
